(19) United States
(12) Patent Application Publication
(10) Pub. No.: US 2002/0005159 A1
(43) Pub. Date: Jan. 17, 2002

(54) METHOD OF PRODUCING THIN SEMICONDUCTOR FILM AND APPARATUS THEREFOR

(76) Inventors: MASATOSHI KITAGAWA, OSAKA (JP); AKIHISA YOSHIDA, KYOTO (JP); MUNEHIRO SHIBUYA, NARA (JP); HIDEO SUGAI, AICHI (JP)

Correspondence Address: RATNER & PRESTIA, ONE WESTLAKES BERWYN SUITE 301, PO BOX 980, VALLEY FORGE, PA, 194820980

(21) Appl. No.: 09/242,866

(22) PCT Filed: Jun. 29, 1998
(86) PCT No.: PCT/JP98/02905

(30) Foreign Application Priority Data
Jun. 30, 1997 (JP) 9-173577

(51) Int. Cl. C30B 15/00; C30B 1/00; C30B 21/06; C30B 27/02; C30B 28/10; C30B 30/04

(52) U.S. Cl. 117/13

(57) ABSTRACT

A method for producing a semiconductor thin film includes the steps of: supplying a source gas to a vacuum chamber; and decomposing the supplied source gas with plasma decomposition using a radio frequency inductive coupled plasma (ICP) generated by application of a radio frequency power, and forming a prescribed semiconductor thin film on a substrate by a chemical vapor deposition process using the decomposed source gas, wherein a crystalline condition of the semiconductor thin film to be formed is controlled by controlling a heating temperature of the substrate during the formation of the semiconductor thin film.

### TECHNICAL FIELD

The present invention relates to a method for producing a semiconductor thin film such as polycrystalline silicon (poly-Si) or amorphous silicon and a production apparatus for implementing the same. Specifically, the present invention relates to a production method and a production apparatus of a semiconductor thin film which can implement with high controllability a thin film growth at a lower temperature than that in the conventional art.

### BACKGROUND ART

Conventionally, a thin film formation of amorphous silicon or polycrystalline silicon is often performed by a chemical vapor deposition (CVD) method which realizes deposition from a vapor phase onto a substrate. Specifically, through a process for thermally decomposing a source gas such as silicon hydride, e.g., SiH₄ (monosilane), Si₂H₆ (disilane), or silicon halogenide, e.g., SiH₂Cl₂ (dichlorosilane), under an atmospheric pressure (a normal pressure) or a low pressure, or through a process for decomposing the source gas with plasma by applying a DC power or a radio frequency power to the source gas under a low pressure, the above-mentioned deposition from the vapor phase is implemented.

For example, in a typical, conventional polycrystalline silicon forming apparatus employing a low pressure CVD apparatus, after evacuating air from a vacuum chamber by a vacuum pump, the vacuum chamber and the substrate therein are heated through an externally-heating type heater so that the source gas which is mainly composed of monosilane (SiH₄) or the like introduced from a gas inlet port is heated at a temperature higher than the decomposing temperature. When intermediate products generated by this thermal decomposition process reaches the substrate, amorphous silicon is deposited in the case where the substrate temperature is set to be lower than about 600° C., whereas polycrystalline silicon is deposited in the case where the substrate temperature is set to be more than about 600° C.

However, in the method for producing the silicon thin film by the conventional low pressure CVD method or the plasma CVD method utilizing a thermal decomposition process or a plasma decomposition process as described above, the formation temperature (the substrate temperature) is required to be set at more than about 600° C. for forming polycrystalline silicon. Therefore, a producing apparatus of the semiconductor thin film becomes more expensive, and only the limited substrate materials can be used. These are significant problems to be solved in order to implement production of a low-priced industrial device. Furthermore, it is difficult to implement formation of the thin film having a large area required for expansion of the application of a polycrystalline silicon thin film because a size of a region to be heated (volume and/or area) is limited depending on the capacity of the heater.

One way to avoid these problems is a plasma CVD method (ECR plasma CVD method) employing microwave electron cyclotron resonance (ECR). In FIG. 6, a typical configuration of an ECR plasma CVD apparatus is schematically shown.

In an apparatus having the configuration shown in FIG. 6, a plasma can be generated even in a low pressure SiH₄ atmosphere of around 1 mTorr. Therefore, a method is proposed of using the apparatus having such a configuration that, for example, after SiH₄ gas is set in a highly excited condition, a microcrystalline silicon film or a polycrystalline silicon film is deposited on the substrate at a relatively low substrate heating temperature of about 300° C. whereas an amorphous silicon film is deposited on the substrate at a further lower substrate heating temperature (e.g., about 50° C.). By this method, a semiconductor (silicon) thin film of high quality is produced at a low temperature.

Hereinafter, the apparatus configuration shown in FIG. 6 will be described in more detail. A vacuum chamber 61 is evacuated through an exhaust port 62. While a microwave is introduced into a plasma generation chamber 65 through a waveguide 63 from a microwave power source 64, a magnetic field is simultaneously applied to the plasma generation chamber 65 by an electromagnetic coil 66. As a source gas, mainly monosilane (SiH₄) gas is introduced into the vacuum chamber 61 from a source gas container (a source gas source) 60 through a gas inlet port 67. By setting intensity of the applied magnetic field so as to satisfy the electron cyclotron resonance condition, a plasma 80 having a high degree of dissociation is obtained in the plasma generation chamber 65. The generated plasma 80 passes through a plasma extracting window 68 to enter the vacuum chamber 61 and reach a substrate holder 69 which is heated at, for example, about 250° C., whereby polycrystalline silicon is deposited on the surface of a substrate 70 disposed on the substrate holder 69.

However, the production method utilizing the above described microwave ECR plasma CVD method has some problems to be solved.

Firstly, in the above method, though formation of the semiconductor thin film can be implemented at a low temperature, a resonance magnetic field is required as shown in the apparatus configuration of FIG. 6.

For example, when a microwave of about 1.25 GHz is introduced into the plasma generation chamber 65, a high magnetic field of 875 Gauss, which is resonant with the above microwave, need to be generated. Therefore, a large magnetic field generation device (e.g., an electromagnetic coil) is required. Due to such a size of a magnet, size of the plasma generation chamber (plasma generation source) 65 is limited. For example, in order to generate the above described high electromagnetic field by the electromagnetic coil 66 as shown in FIG. 6, a large current having an order of hundreds of amperes is required to flow, and thus, a size and weight of the electromagnetic coil 66 becomes significantly large.

Specifically, in a field of Ultra-LSI, since a diameter of a silicon substrate has been getting larger, it is required that a semiconductor thin film is deposited on a wafer having a diameter of about 300 mm. In a liquid crystal display using a thin film transistor (TFT), a number of products of which has been dramatically increasing in these years, it is demanded that a semiconductor thin film is deposited on a large scale substrate having a size of more than 500 mm×500 mm. When designing a microwave ECR plasma CVD apparatus for treating such a large area at one time, a weight of the required electromagnetic coil 66 is calculated to be several hundreds of kilograms. In addition, in order to supply a DC current required for such a electromagnetic coil 66, a power source having an output of several tens of kilowatts is required. Moreover, in order to prevent the electromagnetic coil 66 from being overheated to result in a low operation efficiency, a cooling mechanism such as water cooling is further required.

Thus, the apparatus as a whole becomes larger and more complicated, resulting in a system of low efficiency.

Introduction of the microwave into the plasma generation chamber 65 for generating the ECR plasma 80 is considered as a local emission supply of electric power utilizing the waveguide 63 or a coil antenna. Therefore, a size (volume/area) of a plasma generation region is limited. In other words, it is difficult to deposit a semiconductor thin film over a large area by making the size of the plasma generation region larger because the ECR plasma 80 is ignited at a point.

From consideration of the above points as a whole, it has been conventionally considered difficult to implement a thin film formation over a large area, which is expected to be widely demanded as a field of semiconductor thin film application.

The above described problems can be overcome by using a plurality of small ECR plasma sources or by moving the substrate during the process. However, such countermeasures result in a significant decrease in a deposition rate so that a possibility of forming a semiconductor thin film at a low temperature and at a high rate is eliminated. Thus, a practical application of a method for producing a semiconductor thin film of such a large area has been hindered.

Furthermore, in the production method and apparatus using the conventional ECR plasma source 80 which employs a high magnetic field, a relatively large magnetic field exists in the vicinity of the substrate 70 to be treated. Therefore, the plasma 80 generated in the plasma generation chamber 65 moves along the magnetic field gradient so that charged particles of both ions and electrons are incident on the surface of the substrate 70 at a high energy. Thereby, there is a great possibility of damaging a substrate 70 or a film to be formed on the surface thereof to function as an underlying film. Furthermore, the magnetic field in the vicinity of the substrate 70 is often non-uniform so that the charged particles are likely to be incident non-uniformly onto the substrate 70 and the like. As a result, there is a high possibility of causing non-uniform or local damage. This is one of the factors that hinders the practical application of the above described production method.

### DISCLOSURE OF INVENTION

The present invention is made for solving the above described problems. An objective of the present invention is to provide a method for producing a semiconductor thin film, and a production apparatus therefor, in which a semiconductor thin film of high quality can be produced at a low temperature, and crystallinity of the resultant semiconductor thin film (i.e., a polycrystalline thin film or an amorphous thin film) can be selectively obtained with good controllability by controlling a substrate temperature.

A method for producing a semiconductor thin film of the present invention includes the steps of: supplying a source gas to a vacuum chamber; and decomposing the supplied source gas with plasma decomposition using a radio frequency inductive coupled plasma (ICP) generated by application of a radio frequency power, and forming a prescribed semiconductor thin film on a substrate by a chemical vapor deposition process using the decomposed source gas, wherein a crystalline condition of the semiconductor thin film to be formed is controlled by controlling a heating temperature of the substrate during the formation of the semiconductor thin film, whereby the aforementioned objective can be accomplished.

In one embodiment, the source gas is a gas including silicon.

In one embodiment, the source gas is a mixed gas in which hydrogen is mixed with a gas including silicon.

Preferably, the heating temperature of the substrate during the formation of the semiconductor thin film is set to be in a range from about 50° C. to about 550° C.

A frequency of the radio frequency power to be applied may be set to be about 50 Hz to about 500 MHz.

In one embodiment, the radio frequency inductive coupled plasma is generated by utilizing means for generating a magnetic field provided in a generation region of the radio frequency inductive coupled plasma or in the vicinity thereof.

The means for generating a magnetic field may be an electromagnetic coil. Alternatively, the means for generating a magnetic field may be a permanent magnet having a prescribed magnetic flux density.

Preferably, a pressure in a generation region of the radio frequency inductive coupled plasma during the formation of the semiconductor thin film is set to be about 5×10⁻⁵ Torr to about 2×10⁻² Torr.

In one embodiment, the method further includes the steps of: measuring an emission light spectrum of the radio frequency inductive coupled plasma at least in the vicinity of the substrate; measuring relative ratios (a [Si]/[SiH] ratio and a [H]/[SiH] ratio) among an emission light peak intensity [SiH] from a SiH molecule, an emission light peak intensity [Si] from a Si atom, and an emission light peak intensity [H] from a H atom, in the measured emission light spectrum; and adjusting a prescribed process parameter so that the relative ratios satisfy at least one of ([Si]/[SiH])>1.0 and ([H]/[SiH])>2.0.

The prescribed process parameter to be adjusted may be at least one of a pressure in a generation region of the radio frequency inductive coupled plasma, a supply flow rate of the source gas, a ratio of the supply flow rate of the source gas, and a value of the applied radio frequency power.

An apparatus for producing a semiconductor thin film of the present invention includes: means for supplying a source gas to a vacuum chamber; means for decomposing the supplied source gas with plasma decomposition using a radio frequency inductive coupled plasma (ICP) generated by application of a radio frequency power, and forming a prescribed semiconductor thin film on a substrate by a chemical vapor deposition process using the decomposed source gas; and substrate temperature control means for controlling a heating temperature of the substrate in the chemical vapor deposition process, wherein a crystalline condition of the semiconductor thin film to be formed is controlled by controlling the heating temperature of the substrate during the formation of the semiconductor thin film by the substrate temperature control means, whereby the aforementioned objective can be accomplished.

In one embodiment, the source gas is a gas including silicon.

In one embodiment, the source gas is a mixed gas in which hydrogen is mixed with a gas including silicon.

Preferably, the heating temperature of the substrate during the formation of the semiconductor thin film is set to be in a range from about 50° C. to about 550° C.

A frequency of the radio frequency power to be applied may be set to be about 50 Hz to about 500 MHz.

In one embodiment, the apparatus further includes means for generating a magnetic field provided in a generation region of the radio frequency inductive coupled plasma or in the vicinity thereof.

The means for generating a magnetic field may be an electromagnetic coil. Alternatively, the means for generating a magnetic field may be a permanent magnet having a prescribed magnetic flux density.

Preferably, a pressure in a generation region of the radio frequency inductive coupled plasma during the formation of the semiconductor thin film is set to be about 5×10⁻⁵ Torr to about 2×10⁻² Torr.

In one embodiment, the apparatus further includes: means for measuring an emission light spectrum of the radio frequency inductive coupled plasma at least in the vicinity of the substrate; means for measuring relative ratios (a [Si]/[SiH] ratio and a [H]/[SiH] ratio) among an emission light peak intensity [SiH] from a SiH molecule, an emission light peak intensity [Si] from a Si atom, and an emission light peak intensity [H] from a H atom, in the measured emission light spectrum; and means for adjusting a prescribed process parameter so that the relative ratios satisfy at least one of ([Si]/[SiH])>1.0 and ([H]/[SiH])>2.0.

The prescribed process parameter to be adjusted may be at least one of a pressure in a generation region of the radio frequency inductive coupled plasma, a supply flow rate of the source gas, a ratio of the supply flow rate of the source gas, and a value of the applied radio frequency power.

According to the present invention, a reduction in the formation temperature of a semiconductor thin film, especially of polycrystalline silicon, which is conventionally realized only by using the microwave ECR plasma CVD, is realized by using, in place of the microwave ECR, an inductive coupled plasma CVD (ICPCVD) apparatus which uses inductive coupled plasma (ICP) without utilizing the high magnetic field as a plasma source. By using the inductive coupled plasma (ICP), SiH₄ gas can be decomposed with plasma uniformly over a large deposition area in a low pressure region without necessity for a large-sized magnetic field generation device.

Specifically, in the conventional method, in order to decompose the SiH₄ gas with plasma, which is unlikely to be decomposed because of its high degree of dissociation, a low pressure plasma having a high electron temperature is generated utilizing resonance phenomenon (ECR) between the microwave and the high magnetic field. Therefore, the size of a magnetic field generation device, a waveguide for the microwave, and the like, becomes larger and the miniaturization thereof is difficult. Furthermore, it is also difficult to uniformly deposit a semiconductor thin film over a large area.

On the other hand, the present invention utilizes the fact that the radio frequency inductive coupled plasma, which is a plasma source not using high magnetic field or microwave, can generate a low pressure plasma in a high density plasma condition which is excited uniformly and sufficiently over a large area. Therefore, a film of high quality can be deposited at a sufficiently fast deposition rate without damage.

### BRIEF DESCRIPTION OF DRAWINGS

FIG. 1 is a perspective view schematically showing a configuration of an ICPCVD apparatus in example 1 of the present invention.

FIG. 2 is a graph illustrating the dependency of a light electrical conductivity and a dark electrical conductivity of a silicon thin film deposited according to the present invention, with respect to a temperature of the substrate during formation of the film.

FIG. 3 is a graph illustrating the dependency of a light electrical conductivity and a dark electrical conductivity of a silicon thin film deposited according to the present invention, with respect to the applied radio frequency power during formation of the film.

FIG. 4 is a schematic view of an ICPCVD apparatus in example 2 of the present invention.

FIG. 5 is a graph showing measured data of the light electrical conductivity/dark electrical conductivity ratio (a light-dark electrical conductivity ratio), with respect to various silicon thin films which have been produced while keeping the substrate temperature constant with the other process parameters being variously altered.

FIG. 6 is a schematic view showing the configuration of an ECR plasma CVD apparatus according to the conventional art.

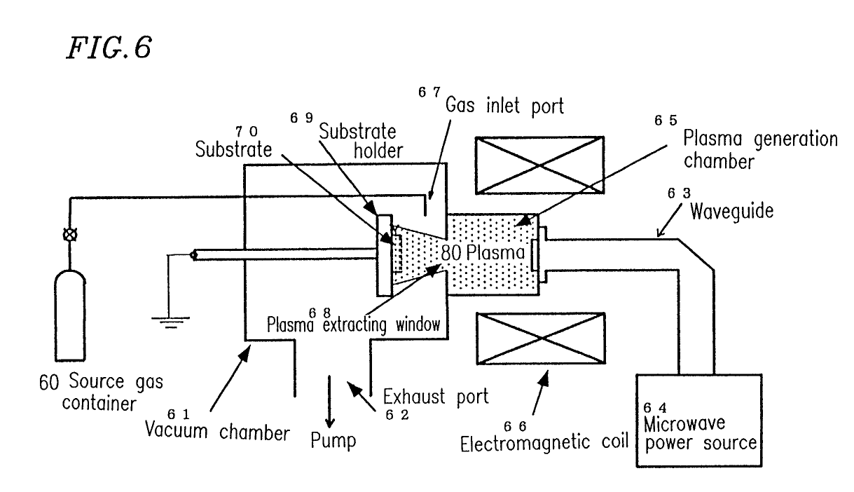

### BEST MODE FOR CARRYING OUT THE INVENTION

Hereinafter, representative embodiments of the present invention will be described with reference to accompanying drawings.

### EXAMPLE 1

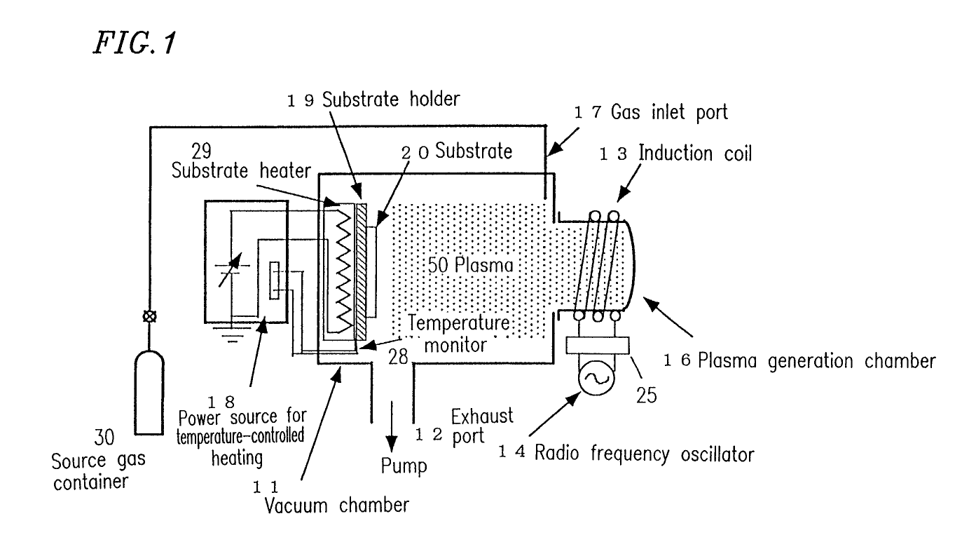

FIG. 1 is a schematic view showing a configuration of the ICPCVD apparatus in example 1 of the present invention.

Specifically, a vacuum chamber 11 is evacuated through an exhaust port 12. A plasma generation chamber 16 is attached to the vacuum chamber 11, and an induction coil 13 is wound around the plasma generation chamber 16. A radio frequency power generated by a radio frequency oscillator 14 and set at a prescribed parameter (e.g., frequency) by an adjuster 25 is applied to the induction coil 13. A portion of the plasma generation chamber 16, at least in the vicinity of a region where the induction coil 13 is located, is made of a insulating material such as a quartz tube. By applying the radio frequency power to the induction coil 13, an inductive magnetic field is generated so that an electromagnetic field is applied to the plasma generation chamber 16.

A source gas including silicon element such as monosilane (SiH₄) gas is introduced into the vacuum chamber 11 from a source gas container (the source gas source) 30 through a gas inlet port 17. By setting a number of turns of the induction coil 13 so as to satisfy the inductive coupled condition with the radio frequency power to be applied, a radio frequency inductive coupled plasma (ICP) 50 having a high degree of dissociation is obtained in the plasma generation chamber 16. The generated plasma 50 is heated by a heating power source (a power source for temperature-controlled heating) 18 using a substrate heater 29, and reaches the substrate holder 19 whose temperature is controlled by a temperature monitor 28. Thus, a silicon thin film (of polycrystalline silicon or amorphous silicon) is deposited on a surface of a substrate 20 disposed on the holder 19.

A frequency of the radio frequency power to be applied to the induction coil 13 only needs to be set at such a frequency that realizes coupling by the induction coil 13 and generation of the discharge plasma 50. For example, it is preferable to be set in the range from about 50 Hz to about 500 MHz. The lower limit of the above described range, about 50 Hz, is a practical AC frequency which is not viewed as DC when viewed from the plasma 50. The upper limit of about 500 MHz is an upper limit of a frequency at which the electric field can be applied by a coil antenna without using a waveguide.

Typically, the frequency of the radio frequency power to be applied to the induction coil 13 is set to be in a range from about 10 MHz to about 100 MHz, e.g., at 13.56 MHz. However, as long as the discharged plasma 50 is generated, the same effect can be obtained in a wide frequency range such as described above.

When the frequency of the applied radio frequency is set at 13.56 MHz as described above, a current required for generating the plasma 50 is as little as several milliamperes, and therefore, a number of turns of the induction coil 13 may be as few as 2 turns. Thus, miniaturization of the entire size of the apparatus can be easily realized.

Although the high density plasma 50 is generated, a magnetic field is generated only in the vicinity of the induction coil 13 whereas it is not generated in the vicinity of the substrate 20 to be treated, which is different from the case with the ECR plasma CVD apparatus. Therefore, charged particles are not incident on the substrate along the magnetic field gradient, which is one of the problems in the ECR plasma CVD apparatus, and thus, damage on the substrate is restrained.

Furthermore, in the apparatus configuration of the present invention, a type of semiconductor thin films to be formed can be properly selected by suitably selecting source gases. For example, for forming a silicon thin film, it is required to supply at least a source gas including a silicon element, such as silicon hydride, e.g., SiH₄ (monosilane) or Si₂H₆ (disilane), or a silicon halogenide, e.g., SiH₂Cl₂ (dichlorosilane). Alternatively, by mixing methane (CH₄) to the source gas to be supplied, a silicon carbide (SiC) film can be formed.

In formation of the semiconductor thin film, a pressure in a generation region of the plasma (the radio frequency inductive coupled plasma=ICP) 50 is preferably set to be in a range from about 5×10⁻⁵ Torr to about 2×10⁻² Torr.

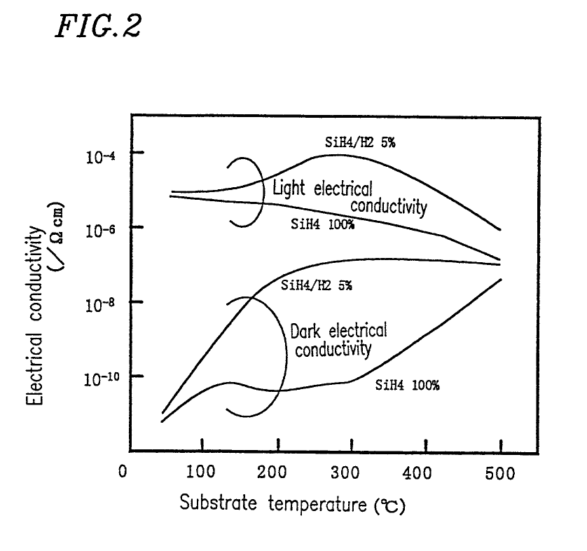

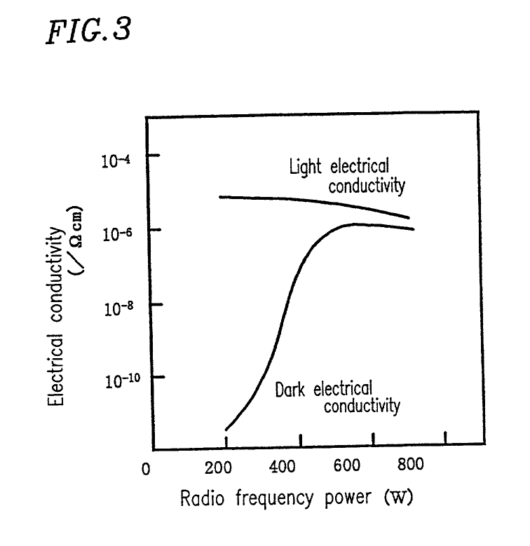

Furthermore, by diluting the source gas including silicon to be supplied (e.g., SiH₄) with a suitable gas such as hydrogen, or by increasing the radio frequency power to be applied to the induction coil 13, a polycrystalline silicon film can be formed. This will be further described with reference to FIGS. 2 and 3.

In FIG. 2, with respect to the case where a SiH₄/H₂ mixture source gas made by diluting a 100% SiH gas having a flow rate of 5 sccm with a hydrogen gas having a flow rate of 20 sccm is introduced (marked as “SiH₄/H₂ 5%”) and to the case where SiH₄ is introduced at a flow rate of 10 sccm without being diluted (marked as “SiH₄ 100%”); measured value of an electrical conductivity (a light electrical conductivity and a dark electrical conductivity) of a silicon thin film deposited on the surface of the substrate 20 by supplying the source gas so that a pressure inside the vacuum chamber 11 is set at 1 mTorr, is shown with heating temperatures of the substrate 20 during the formation as parameters.

As seen from FIG. 2, in both cases, in a substrate temperature range from room temperature to about 150° C., a satisfactory light electrical conductivity and a light-dark ratio (i.e., a ratio of the light electrical conductivity and the dark electrical conductivity) are obtained. This means that an amorphous silicon film is formed. Furthermore, from the result of the X-ray diffraction, formation of the hydrogenated amorphous silicon is confirmed.

On the other hand, at substrate temperatures of more than 150° C., characteristics of the film to be formed are different depending on whether the dilution with hydrogen is performed or not. That is, with a hydrogen dilution, the dark electrical conductivity increases with respect to the substrate temperature of more than 150° C., which means a crystallized film is deposited. In practice, from the result of the X-ray diffraction, crystallization of the deposited film is confirmed. In contrast, without a hydrogen dilution, the dark electrical conductivity changes little until the substrate temperature increases to about 400° C. In this case, from the result of the X-ray diffraction, it is confirmed that the film is not crystallized and remains in an amorphous state.

Thus, when the hydrogen dilution is performed under the above described conditions, an amorphous silicon film is deposited at a substrate temperature in the range up to about 150° C., whereas a polycrystalline silicon film is deposited at a substrate temperature of over about 150° C. However, the above-mentioned critical temperature of around 150° C., at which a film to be deposited is transformed from amorphous to polycrystalline (crystalline), may change depending on a supply amount and type of the source gas, the apparatus configuration, an applied power, a discharge frequency, and the like.

On the other hand, FIG. 3 shows changes in the light electrical conductivity and the dark electrical conductivity of the silicon thin film formed at room temperature with supplying the above-mentioned 5% hydrogen-diluted SiH₄ gas under the conditions of: a pressure in the vacuum chamber 11 of about 1 mTorr; a constant substrate temperature of about 250° C.; and an applied radio frequency power being varied in the range from about 100 W to about 1000 W. As seen from this, the dark electrical conductivity increases in the relatively high power range from about 500 W to about 1000 W, and crystallization of the deposited film in this range is confirmed.

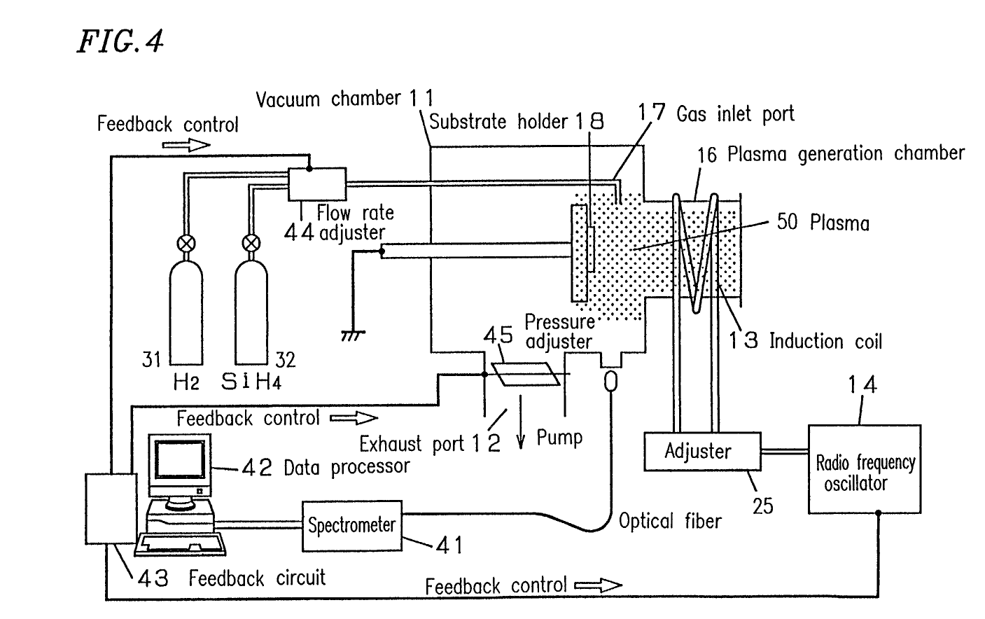

Although not shown in FIG. 1, in practice, the apparatus configuration of FIG. 1 can include a flow rate adjuster for adjusting a flow rate of a gas from the source gas container 30, a pressure adjuster for adjusting a pressure inside the vacuum chamber 11 by adjusting an exhausting rate from the exhaust port 12 to the pump, and the like. These adjusters are shown in the configuration of FIG. 4, which will be described hereinafter.

Furthermore, in order to be adapted to the above described hydrogen dilution of the source gas, it is only required to provide, as a source gas container 30, a container 31 for hydrogen gas (H₂) and a container 32 for a gas including silicon element such as SiH₄, respectively, as shown in FIG. 4.

### EXAMPLE 2

FIG. 4 is a schematic view showing a configuration of an ICPCVD apparatus according to example 2 of the present invention.

In the apparatus configuration of FIG. 4, the same reference numerals are given to components corresponding to the configuration of FIG. 1, and descriptions thereof are omitted herein. Moreover, the power source for heating the substrate (power source for temperature-controlled heating) 18, the substrate heater 29, and the temperature monitor 28, which are shown in FIG. 1, are omitted in FIG. 4.

In the apparatus configuration of FIG. 4, during a deposition process, a spectrometric analysis of emitted light is performed by introducing light from the generated plasma 50 into a spectrometer 41 through an optical fiber or the like, thereby enabling to detect variations of a prescribed emission light peak intensity. Furthermore, by monitoring the detected emission light peak intensity through a data processor 42 and constituting a feedback circuit 43 to a discharge pressure, a discharge power and a supply flow rate, a feedback control is performed with respect to a flow rate adjuster 44, a pressure adjuster 45 and a radio frequency oscillator (power source) 14. Therefore, by controlling the emission light peak intensity of Si, SiH and H (which are referred to as [Si], [SiH] and [H], respectively, in the present description) from the plasma 50 so as to be at the prescribed values, a semiconductor thin film of high quality can be stably produced.

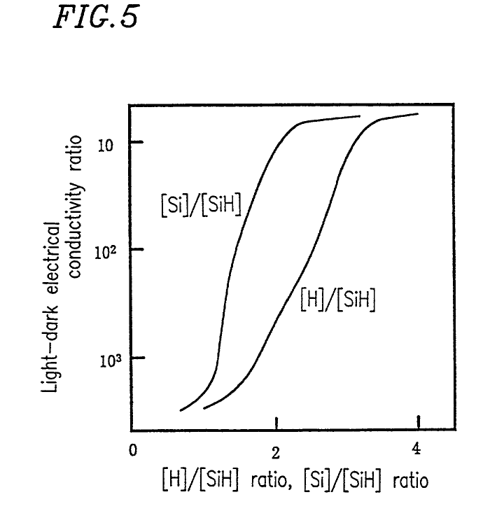

FIG. 5 shows the measured data of ratio of the light electrical conductivity/the dark electrical conductivity (the light-dark electrical conductivity ratio) with respect to various silicon thin films which are produced with maintaining substrate temperatures constant at about 250° C. while varying process parameters such as a radio frequency power to be applied, a flow rate of the source gas (e.g., SiH₄) to be supplied, a flow rate ratio of the source gas to be supplied (e.g., a flow rate ratio of H₂ and SiH₄=a dilution rate), a pressure in the generation region of the plasma 50, or the like. Herein, an abscissa axis shows relative ratios (a [Si]/[SiH] ratio and a [H]/[SiH] ratio) among an emission light peak intensity [SiH] from SiH molecules seen in the vicinity of about 400 nm to about 420 nm, an emission light peak intensity [Si] from Si atoms seen in the vicinity of about 288 nm (from about 280 nm to about 290 nm), and an emission light peak intensity [H] from H atoms seen in the vicinity of about 618 nm (from about 610 nm to about 620 nm).

As seen from FIG. 5, when relatively satisfying [Si]>[SiH] or [H]>[SiH], i.e., when a [Si]/[SiH] ratio or a [H]/[SiH] ratio becomes greater, the light-dark electrical conductivity ratio of the produced silicon thin film becomes smaller, thereby resulting in the condition wherein the crystallization of a thin film to be deposited can be easily realized.

Therefore, in order to obtain a crystalline silicon thin film (of polycrystalline silicon) while maintaining a low substrate temperature during a thin film formation, it is only required to observe the emission light spectrometry of the plasma as described above and adjust various process parameters, for example, a radio frequency power to be applied, a flow rate of the source gas (e.g., SiH₄) to be supplied, a flow rate ratio of the source gas (e.g., a flow rate ratio of H₂ and SiH₄), or a pressure in the generation region of the plasma 50 so that the aforementioned relative ratios of the emission light peak intensities among Si, SiH and H ([Si], [SiH] and [H]) satisfy [Si]>[SiH] or [H]>[SiH]. More specifically, by adjusting the above-mentioned various process parameters (for example, a radio frequency power to be applied, a flow rate of the source gas to be supplied, a flow rate ratio of the source gas, or a pressure in the generation region of the plasma 50) so that at least one of ([Si]/[SiH])>1.0 and ([H]/[SiH])>2.0 is satisfied, a crystalline (polycrystalline) silicon thin film of high quality can be obtained.

Alternatively, when a thin film formation is performed at a substrate temperature of about 50° C. while the various process parameters are maintained such that the above-mentioned ratios among the emission light peak intensities of Si, SiH and H satisfy [Si]>[SiH] or [H]>[SiH], a hydrogenated amorphous silicon film of high quality can be obtained.

Thus, the above-described emission light spectrometry analysis of plasma (specifically, analysis of a [Si]/[SiH] ratio and a [H]/[SiH] ratio which are relative ratios among the emission light peak intensities of Si, SiH and H) is effective as a process monitor for realizing thin film formation with excellent controllability with respect to whether the film is amorphous or crystalline when producing a semiconductor thin film of high quality at a low temperature.

A film formation rate under the various conditions when measuring data shown in FIG. 5 as set forth above is about 1 A/second to about 10 A/second, which is a sufficiently practical rate.

The above-mentioned apparatus configurations of Examples 1 and 2, as shown in FIG. 1 or FIG. 4, employ an inductive coupling device with an external coil configuration in which a solenoid-coil type external coil disposed in the vicinity of the plasma generation chamber 16 is used as the induction coil 13 serving as means for generating magnetic field for generating the radio frequency inductive coupled plasma (ICP) 50. However, application of the present invention is not limited thereto. Completely similar advantages can be obtained for the cases of different configurations, for example, for an inductive coupling device with a spiral-type coil configuration having a coil wound on the same plane, an inductive coupling device with an internal coil configuration having an induction coil disposed inside the reaction chamber, and further for configurations in which an assisting magnet is further added to the above-described configurations. Alternatively, a permanent magnet having a predetermined magnetic flux density may be provided in place of the electromagnetic coil.

### Industrial Applicability

As described above, according to the present invention, a radio frequency inductive coupled plasma, which is a plasma source capable of generating a low pressure plasma over a large area without using a high magnetic field or microwave, is utilized for plasma decomposition of the source gas when forming a semiconductor thin film by a CVD method. Thus, the source gas such as SiH₄ gas or the like can be decomposed with plasma uniformly over a large deposition area in a low pressure region without the necessity of a large magnetic field generation device. As a result, a semiconductor thin film (an amorphous film or a polycrystalline film) of high quality can be deposited at a sufficiently fast deposition rate without damaging a substrate or a film formed on a surface thereof to function as an underlying film. Thereby, a semiconductor element of high performance can be produced.

1. A method for producing a semiconductor thin film, comprising the steps of:
supplying a source gas to a vacuum chamber; and
decomposing the supplied source gas with plasma decomposition using a radio frequency inductive coupled plasma (ICP) generated by application of a radio frequency power, and forming a prescribed semiconductor thin film on a substrate by a chemical vapor deposition process using the decomposed source gas,
wherein a crystalline condition of the semiconductor thin film to be formed is controlled by controlling a heating temperature of the substrate during the formation of the semiconductor thin film.

2. A method for producing the semiconductor thin film according to claim 1, wherein the source gas is a gas including silicon.

3. A method for producing the semiconductor thin film according to claim 1, wherein the source gas is a mixed gas in which hydrogen is mixed with a gas including silicon.

4. A method for producing the semiconductor thin film according to claim 1, wherein the heating temperature of the substrate during the formation of the semiconductor thin film is set to be in a range from about 50° C. to about 550° C.

5. A method for producing the semiconductor thin film according to claim 1, wherein a frequency of the radio frequency power to be applied is set to be about 50 Hz to about 500 MHz.

6. A method for producing the semiconductor thin film according to claim 1, wherein the radio frequency inductive coupled plasma is generated by utilizing means for generating a magnetic field provided in a generation region of the radio frequency inductive coupled plasma or in the vicinity thereof.

7. A method for producing the semiconductor thin film according to claim 6, wherein the means for generating a magnetic field is an electromagnetic coil.

8. A method for producing the semiconductor thin film according to claim 6, wherein the means for generating a magnetic field is a permanent magnet having a prescribed magnetic flux density.

9. A method for producing the semiconductor thin film according to claim 1, wherein a pressure in a generation region of the radio frequency inductive coupled plasma during the formation of the semiconductor thin film is set to be about 5×10⁻⁵ Torr to about 2×10⁻² Torr.

10. A method for producing the semiconductor thin film according to claim 1, further comprising the steps of:
measuring an emission light spectrum of the radio frequency inductive coupled plasma at least in the vicinity of the substrate;
measuring relative ratios (a [Si]/[SiH] ratio and a [H]/[SiH] ratio) among an emission light peak intensity [SiH] from a SiH molecule, an emission light peak intensity [Si] from a Si atom, and an emission light peak intensity [H] from a H atom, in the measured emission light spectrum; and
adjusting a prescribed process parameter so that the relative ratios satisfy at least one of ([Si]/[SiH])>1.0 and ([H]/[SiH])>2.0.

11. A method for producing the semiconductor thin film according to claim 10, wherein the prescribed process parameter to be adjusted is at least one of a pressure in a generation region of the radio frequency inductive coupled plasma, a supply flow rate of the source gas, a ratio of the supply flow rate of the source gas, and a value of the applied radio frequency power.

12. An apparatus for producing a semiconductor thin film, comprising:
means for supplying a source gas to a vacuum chamber;
means for decomposing the supplied source gas with plasma decomposition using a radio frequency inductive coupled plasma (ICP) generated by application of a radio frequency power, and forming a prescribed semiconductor thin film on a substrate by a chemical vapor deposition process using the decomposed source gas; and
substrate temperature control means for controlling a heating temperature of the substrate in the chemical vapor deposition process,
wherein a crystalline condition of the semiconductor thin film to be formed is controlled by controlling the heating temperature of the substrate during the formation of the semiconductor thin film by the substrate temperature control means.

13. An apparatus for producing the semiconductor thin film according to claim 12, wherein the source gas is a gas including silicon.

14. An apparatus for producing the semiconductor thin film according to claim 12, wherein the source gas is a mixed gas in which hydrogen is mixed with a gas including silicon.

15. An apparatus for producing the semiconductor thin film according to claim 12, wherein the heating temperature of the substrate during the formation of the semiconductor thin film is set to be in a range from about 50° C. to about 550° C.

16. An apparatus for producing the semiconductor thin film according to claim 12, wherein a frequency of the radio frequency power to be applied is set to be about 50 Hz to about 500 MHz.

17. An apparatus for producing the semiconductor thin film according to claim 12, further comprising means for generating a magnetic field provided in a generation region of the radio frequency inductive coupled plasma or in the vicinity thereof.

18. An apparatus for producing the semiconductor thin film according to claim 17, wherein the means for generating a magnetic field is an electromagnetic coil.

19. An apparatus for producing the semiconductor thin film according to claim 17, wherein the means for generating a magnetic field is a permanent magnet having a prescribed magnetic flux density.

20. An apparatus for producing the semiconductor thin film according to claim 12, wherein a pressure in a generation region of the radio frequency inductive coupled plasma during the formation of the semiconductor thin film is set to be about 5×10⁻⁵ Torr to about 2×10⁻² Torr.

21. An apparatus for producing the semiconductor thin film according to claim 12, further comprising:
means for measuring an emission light spectrum of the radio frequency inductive coupled plasma at least in the vicinity of the substrate;
means for measuring relative ratios (a [Si]/[SiH] ratio and a [H]/[SiH] ratio) among an emission light peak intensity [SiH] from a SiH molecule, an emission light peak intensity [Si] from a Si atom, and an emission light peak intensity [H] from a H atom, in the measured emission light spectrum; and
means for adjusting a prescribed process parameter so that the relative ratios satisfy at least one of ([Si]/[SiH])>1.0 and ([H]/[SiH])>2.0.

22. An apparatus for producing the semiconductor thin film according to claim 21, wherein the prescribed process parameter to be adjusted is at least one of a pressure in a generation region of the radio frequency inductive coupled plasma, a supply flow rate of the source gas, a ratio of the supply flow rate of the source gas, and a value of the applied radio frequency power.
